(19) United States
(12) Patent Application Publication
(10) Pub. No.: US 2026/0078528 A1
(43) Pub. Date: Mar. 19, 2026

(54) METHOD FOR PREPARING THE FRONT FACE OF A POLYCRYSTALLINE SILICON CARBIDE SLAB

(71) Applicant: Soitec, BERNIN (FR)

(72) Inventors: Kassem Alassaad, BERNIN (FR); Sylvain Monnoye, Le Bourget-du-Lac (FR); Catherine Moisson, Le Bourget-du-Lac (FR); Séverin Rouchier, BERNIN (FR); Guillaume Berre, BERNIN (FR)

(21) Appl. No.: 19/106,544

(22) PCT Filed: Aug. 23, 2023
(86) PCT No.: PCT/FR2023/051286

§ 371 Date: Feb. 25, 2025

(30) Foreign Application Priority Data
Sep. 1, 2022 (FR) FR2208794

(51) Int. Cl. C30B 33/06; C30B 29/36

(52) U.S. Cl. CPC C30B 33/06; C30B 29/36

(57) ABSTRACT

A method for polishing the front face of a polycrystalline silicon carbide slab comprising a surface region at least partially work damaged under the effect of grinding, comprises:
the relative movement of a rotating grinding wheel and the polycrystalline silicon carbide slab until, with the rotating grinding wheel in contact with the front face of the slab, a layer of the polycrystalline silicon carbide slab has been removed, said layer comprising the at least partially work-hardened surface region and having a thickness of less than or equal to 3 μm;
the halting of the relative movement and maintaining the rotating grinding wheel in contact with the front face of the polycrystalline silicon carbide slab for a period of time of greater than 15 seconds.

### CROSS-REFERENCE TO RELATED APPLICATIONS

This application is a national phase entry under 35 U.S.C. § 371 of International Patent Application PCT/FR2023/051286, filed Aug. 23, 2023, designating the United States of America and published as International Patent Publication WO 2024/047305 A1 on Mar. 7, 2024, which claims the benefit under Article 8 of the Patent Cooperation Treaty of French Patent Application Serial No. FR2208794, filed Sep. 1, 2022.

### TECHNICAL FIELD

The present disclosure relates to a process for the preparation of the front face of a polycrystalline silicon carbide slab, to a process for the manufacture of a polycrystalline silicon carbide slab using the process for the preparation of the front face of the slab, and to a process for the preparation of a multilayer structure using the process for the manufacture of a polycrystalline silicon carbide slab.

### BACKGROUND

Silicon carbide (SiC) is increasingly widely used in power electronics applications, in particular, to meet the needs of growing ranges of electronics, such as, for example, electric vehicles. Power devices and integrated power-supply systems based on single-crystal SiC can actually manage a much higher power density than their conventional silicon counterparts, and do so with active regions of smaller size.

Nevertheless, the substrates made of single-crystal SiC intended for the microelectronics industry remain expensive and difficult to supply in large sizes. It is thus advantageous to resort to layer transfer solutions to produce composite structures typically comprising a thin layer made of single-crystal SiC (also referred to as monocrystalline or m-SiC) on a lower cost polycrystalline SiC (also referred to as p-SiC) support substrate.

One well-known thin-layer transfer solution is the SMART CUT™ process. Such a process makes it possible, for example, to manufacture a composite structure comprising a thin layer made of single-crystal SiC, withdrawn from a donor substrate made of single-crystal SiC, in direct contact with a support substrate made of polycrystalline SiC.

Such a support substrate made of polycrystalline SiC can, for example, be formed by a vapor deposition of p-SiC on a growth substrate (for example, a graphite substrate), so as to form a relatively thick p-SiC slab (for example, from 0.4 to 3 mm in thickness), followed by removal of the growth substrate and by thinning of the p-SiC slab, so as to obtain one or more p-SiC wafers having a desired shape (in particular, a bevelled periphery) and a desired thickness.

The thinning comprises, for example, successively a very coarse thinning (by electrical discharge machining or grinding), which will remove, for example, a thickness on the order of 150 μm or more, a coarse grinding, which will remove, for example, a thickness on the order of 20 μm, and a fine grinding, which will remove, for example, a thickness on the order of 3 μm. Preferably, such a thinning is carried out on the front and rear faces of the polycrystalline silicon carbide slab. When the polycrystalline silicon carbide slab is thinner, for example, with a thickness of 400 μm, the very coarse grinding can be omitted.

The thinning makes it possible to obtain a self-supporting wafer, that is to say the thickness of which is such that it does not break or deform plastically under the effect of its own weight. Such a thickness is, for example, greater than or equal to 325 μm, preferably on the order of 350 μm.

The thinning of the slab can be followed by stages of surface finishing of the wafer targeted, in particular, at rendering it smoother.

Nevertheless, it remains difficult to produce high-quality bonding between two single-crystal SiC and polycrystalline SiC substrates, since managing the surface condition and roughness of the substrates is complex.

By way of example, atomic diffusion bonding (ADB) involving a silicon layer of 10 nm requires a roughness of less than 10 Å RMS. Such bonding comprises the deposition of silicon under vacuum and then bringing the two substrates into contact. The structure is subsequently heated to enable the diffusion of the silicon and thus the bonding of the substrates.

While the use of a grinding wheel having very small grains (size of less than 1.5 μm, i.e., a mesh of greater than 15,000) makes it possible to obtain a very low roughness on a single-crystal material, the performance qualities achieved with this same type of grinding wheel on a polycrystalline material, such as polycrystalline silicon carbide, are neither reproducible nor sufficiently satisfactory to enable effective bonding of a single-crystal SiC substrate to a polycrystalline SiC substrate. This is because the removal of matter by the teeth of such a type of grinding wheel is non-uniform at the grains and at the grain boundaries, for this reason generating a form of roughness.

Moreover, while chemical mechanical polishing, a smoothing technique known to a person skilled in the art under the name CMP, is an effective process for single-crystal substrates, this also results in the display of the grain boundaries on a polycrystalline SiC substrate and thus in a roughness that is too great to enable good bonding of a single-crystal SiC substrate to a polycrystalline SiC substrate.

### BRIEF SUMMARY

An aim of the present disclosure is to design a process for the preparation of the front face of a p-SiC substrate to enable high-quality bonding of a thin layer of a single-crystal material to the front face.

To this end, the present disclosure provides a process for polishing the front face of a polycrystalline silicon carbide slab comprising a surface region at least partially work-damaged under the effect of grinding, comprising:
the relative movement of a rotationally driven grinding wheel and of the polycrystalline silicon carbide slab up to the removal from the polycrystalline silicon carbide slab, with the rotating grinding wheel in contact with the front face of the slab, of a layer comprising the at least partially work-damaged surface region and exhibiting a thickness of less than or equal to 3 μm, and
the halting of the relative movement and the holding of the rotating grinding wheel in contact with the front face of the polycrystalline silicon carbide slab for a period of time of greater than 15 seconds.

The holding of the rotating grinding wheel in contact with the front face of the polycrystalline silicon carbide slab for a period of time makes it possible to use the grinding wheel in “rubbing” mode to polish the front face of the p-SiC slab, without removing matter. The displaying of the grain boundaries of the p-SiC substrate observed in more conventional polishing processes, such as chemical mechanical polishing, is then avoided, which thus makes it possible to obtain a level of roughness of the front face compatible with the bonding of a layer of a single-crystal material.

Some preferred but non-limiting aspects of this process are as follows:
the grinding wheel exhibits a greater hardness than the maximum hardness making possible the removal of a non-work-damaged layer of the same thickness as the at least partially work-damaged surface region made of polycrystalline silicon carbide;
the grinding wheel comprises diamond grains coated in a binder, the size of the diamond grains being greater than 2 μm (mesh 12,000);
during the relative movement of the grinding wheel and the polycrystalline silicon carbide slab, the relative speed of the grinding wheel and the front face of the polycrystalline silicon carbide slab is between 0.05 μm/s and 0.5 μm/s, preferably between 0.1 μm/s and 0.45 μm/s, more preferably between 0.15 μm/s and 0.45 um/s, up to the removal of the thickness of less than or equal to 3 μm from the polycrystalline silicon carbide slab;
the holding of the rotating grinding wheel in contact with the front face of the polycrystalline silicon carbide slab is carried out for a period of time greater than or equal to 30 seconds, preferably a period of time of greater than or equal to 40 seconds;
the holding of the rotating grinding wheel in contact with the front face of the polycrystalline silicon carbide slab for a period of time greater than or equal to 30 seconds, preferably a period of time greater than or equal to 40 seconds, is divided up into several sequences;
the process additionally comprises, subsequent to the halting of the relative movement and to the holding of the rotating grinding wheel in contact with the front face of the polycrystalline silicon carbide slab, an additional stage of relative movement of the grinding wheel and the front face of the polycrystalline silicon carbide slab up to the removal, with the rotating grinding wheel in contact with the front face of the slab, of an additional thickness from the polycrystalline silicon carbide slab of less than or equal to 1 μm;
the rotational speed of the grinding wheel during the polishing is between 10 m/s and 45 m/s, preferably between 10 m/s and 25 m/s;
during the polishing, the front face of the polycrystalline silicon carbide slab is driven in rotation at a speed between 200 rev/min and 600 rev/min.

The present disclosure applies to a process for the manufacture of a polycrystalline silicon carbide slab comprising the thinning by grinding of a thick polycrystalline silicon carbide slab on at least its front face, so as to obtain a thinned polycrystalline silicon carbide slab, and the polishing of the front face of the thinned polycrystalline silicon carbide slab in accordance with the present disclosure. The thinning of the thick polycrystalline silicon carbide slab on at least its front face can be carried out by way of a grinding wheel, the size of the grains of which is of between 10 μm (mesh 2000) and 30 μm (mesh 600).

The present disclosure also applies to a process for the preparation of a multilayer structure comprising the manufacture of a polycrystalline silicon carbide slab in accordance with the present disclosure, the provision of a substrate that is a donor of a layer to be transferred and the transfer of the layer to be transferred from the donor substrate onto the front face of the polycrystalline silicon carbide slab. The donor substrate can be a single-crystal silicon carbide substrate. The transfer stage can comprise the formation of a weakened zone by implantation of atomic entities in the donor substrate so as to delimit the layer to be transferred, the bonding of the implanted face of the donor substrate to the front face of the polycrystalline silicon carbide slab and the detachment from the donor substrate along the weakened zone. The bonding can be direct bonding, for example, atomic diffusion bonding.

### BRIEF DESCRIPTION OF THE DRAWINGS

Other characteristics and advantages of the present disclosure will become apparent from the detailed description that will follow, with reference to the appended drawings, in which:

FIG. 1 represents an abrasive grain in the binder of a grinding wheel, before (left-hand representation) and after (right-hand representation) blunting;

FIG. 2 represents different states of wear of an abrasive grain at the periphery of a grinding wheel; and

FIG. 3 compares the bonding efficiency and haze value of polycrystalline silicon carbide slabs (arbitrary unit indicative of roughness), the front face of which has been prepared according to a process of the state of the art, with the bonding efficiencies and the haze values of slabs, the front face of which has been prepared according to two different embodiments of the process of the present disclosure.

For reasons of readability, the drawings are not necessarily produced to scale.

### DETAILED DESCRIPTION

The present disclosure relates to the polishing of the front face of a p-SiC substrate to enable high-quality bonding of a thin layer of a single-crystal material to the front face. This surface preparation is carried out by way of a grinding tool, such as a grinding wheel, instead of the tools conventionally used for polishing, such as chemical mechanical polishing tools. This is because chemical mechanical polishing or CMP makes it possible to achieve very low roughnesses on single-crystal substrates. However, this process reveals the grain boundaries of a polycrystalline silicon carbide substrate, thus creating a new form of roughness.

The present disclosure relates more particularly to the polishing of the front face of a polycrystalline silicon carbide slab, which comprises, at least on the side of its front face, an at least partially work-damaged surface region generated by grinding. Such grinding could be carried out to thin the polycrystalline silicon carbide slab beforehand on at least its front face, preferably on its front face and on its rear face, for example, using a grinding wheel having coarse grains (typically abrasive grains with a size between 10 μm and 18 μm, i.e., a mesh between 1000 and 2000).

Any grinding leaves an at least partially work-damaged surface region, which is also referred to in the industry as a “damaged layer.” In other words, following the grinding, the slab exhibits, on its front face, a surface region in which the crystal is disorganized with scratches and fractured zones. The thickness of the work-damaged surface region depends on the grinding carried out: the coarser the grinding, the thicker the work-damaged surface region. The thickness of the work-damaged surface region is typically between 500 nm and 1 μm.

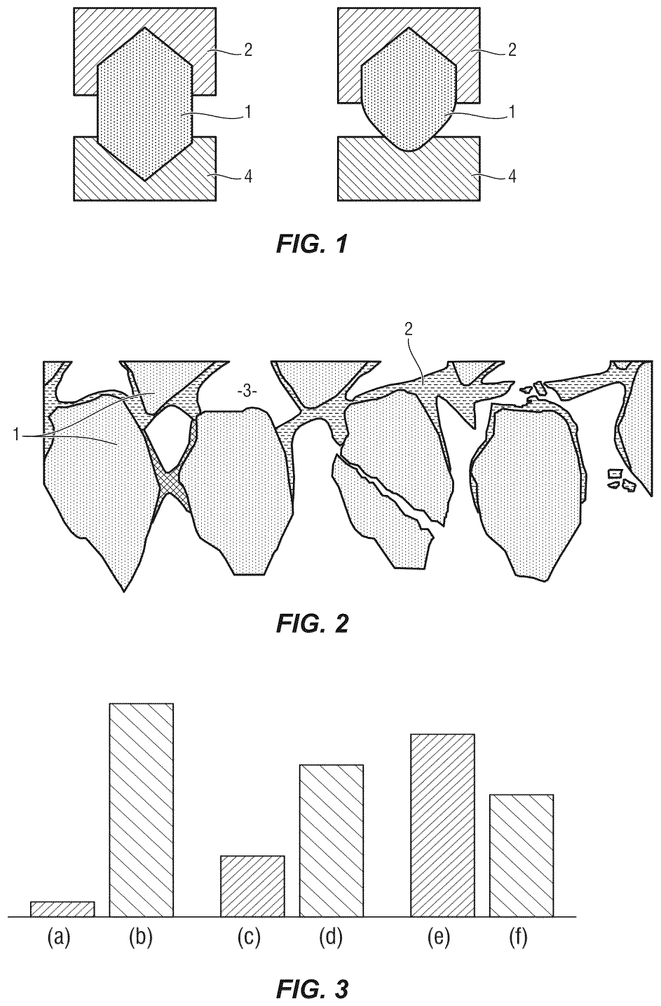

With reference to FIGS. 1 and 2, the term “grinding wheel” refers to a tool having symmetry of revolution comprising mainly grains made of an abrasive material—referred to herein as abrasive grains 1—embedded in a binder 2 exhibiting pores 3, everything being deposited on a support perpendicular to the axis of revolution of the grinding wheel. By way of example, the binder 2 can comprise resins, ceramics or metals. The abrasive grains 1 are, for example, diamond grains. The binder 2 defines overall a surface opposite the support on which abrasive grains 1 protrude, rendering the surface abrasive.

Such grinding wheels are conventionally used to remove matter to thin substrates in “grinding”stages.

Typically, the substrate 4 to be thinned is brought into contact on its front face with the abrasive surface of a rotating grinding wheel (see FIG. 1). A relative axial movement of the grinding wheel and of the substrate to be thinned along the axis of revolution of the grinding wheel makes it possible to apply pressure to the front face of the substrate 4. Under the effect of the pressure, each grain of abrasive matter on the periphery of the grinding wheel then acts as a separate cutting tool that causes a tiny chip of the substrate to be thinned to be removed from its front face. As the abrasive grains become blunt (see FIG. 1, moving from left to right), the pressure and the heat generated by the machining cause the blunted abrasive grains to break and then split (see FIG. 2) so as to cause new abrasive grains with brand new sharp edges to appear at the periphery and to thus regenerate the abrasiveness of the surface of the grinding wheel. The removal of matter from the substrate to be thinned continues with new abrasive grains as long as the grinding wheel and the substrate are in relative translational movement.

Methods of the present disclosure involve using such a grinding wheel not simply for removing matter from a polycrystalline silicon carbide slab but also for polishing the front face of the slab, by contact between the front face of the slab and the abrasive surface of the rotating grinding wheel.

To this end, the process according to the present disclosure for polishing the front face of a polycrystalline silicon carbide slab, comprising an at least partially work-damaged surface region as described above, comprises:
the relative movement of the rotationally driven grinding wheel and the polycrystalline silicon carbide slab up to the removal from the polycrystalline silicon carbide slab, with the rotating grinding wheel in contact with the front face of the slab, of a layer comprising the at least partially work-damaged surface region and exhibiting a thickness of less than or equal to 3 μm, and
the halting of the relative movement and the holding of the rotating grinding wheel in contact with the front face of the polycrystalline silicon carbide slab for a period of time of greater than 15 seconds.

The relative movement of the grinding wheel and of the polycrystalline silicon carbide slab up to removing at least the at least partially work-damaged surface region makes it possible to blunt the grains of the grinding wheel without, however, promoting the splitting thereof. Thus, when the rotating grinding wheel is held in contact with the front face of the slab following the halting of the relative movement of the slab and of the grinding wheel, it is the blunted grains that rub against the front face of the slab and not new, very sharp, grains. This rubbing action ensures gentle polishing of the front face without revealing the boundaries between the silicon carbide grains.

The holding of the rotating grinding wheel in contact with the front face of the polycrystalline silicon carbide slab without relative axial movement of the slab and of the grinding wheel for a period of time of less than 5 s can be carried out conventionally to protect the grinding tool, for example, to avoid large variations in the supply current of the motor. The holding of the rotating grinding wheel in contact with the front face of the polycrystalline silicon carbide slab for a period of time of more than 15 seconds according to the present disclosure makes it possible to observe a decrease in the surface roughness and a significant polishing effect.

Subsequently, the choice of the grinding wheel for the implementation of the process according to the present disclosure is considered.

Different types of grinding wheels are distinguished, depending, for example, on the size of the abrasive grains of the grinding wheels or on their hardness.

It should be noted that the hardness of the grinding wheel is defined as being a measure of the force for holding the grains in the grinding wheel. The harder a grinding wheel, the less easily the blunted grains detach from the grinding wheel, so as to regenerate the abrasive surface of the grinding wheel. Conversely, the less hard the grinding wheel, the more easily the rows of abrasive grains split and succeed one another. The hardness of the grinding wheel depends on the nature of the binder, on the porosity and on the size of the abrasive grains.

In order to remove matter, a person skilled in the art conventionally chooses a grinding wheel that is not too hard, so as to continually regenerate cutting grains. In addition, a grinding wheel that is too hard is less effective in removing matter and creates a risk of heating and thus of breakage of the grinding wheel or of the slab-and of jamming-and thus of scratches on the slab.

In order to carry out the polishing process according to the present disclosure, a harder grinding wheel than the grinding wheels conventionally used to remove matter is used. This is because the partially work-damaged nature of the surface region to be removed advantageously makes possible the blunting of the abrasive grains of the harder grinding wheel without causing breakage or jamming of the grinding wheel. In addition, because the grinding wheel is harder, blunting of the grains without causing them to split is facilitated.

Thus, a grinding wheel with a hardness greater than the maximum hardness making possible the removal of a non-work-damaged layer of the same thickness as the at least partially work-damaged surface region to be removed and made of the same material as the surface region is preferably chosen. In other words, the grinding wheel preferably used is too hard to remove a non-work-damaged layer made of the same material and of the same thickness as the partially work-damaged surface region to be removed, in particular, without causing breakage or jamming.

By way of example, the grinding wheel used is a grinding wheel from Accretech referenced with the letter I or higher in alphabetical order, for example, the ACCRETECH® HW8000VB-1144 grinding wheel.

Regarding the choice of the size of the grains of the grinding wheel, for a single-crystal substrate, it is known to use grinding wheels exhibiting abrasive grains that are all the smaller since it is desired to obtain, following the grinding, a surface exhibiting a low roughness. Thus, a grinding wheel comprising very small grains (typically a size of less than 1.5 μm, i.e., a mesh of greater than 15,000) makes it possible, for example, to obtain free surfaces of single-crystal silicon carbide substrates of very low roughness, of less than 1 nm RMS.

However, the result obtained with this type of grinding wheel having very small grains on a polycrystalline silicon carbide slab remains insufficient to enable quality bonding of a single-crystal substrate to the slab, for example, bonding carried out in the context of the SMART CUT™ process.

It was noticed that grinding wheels having very small grains tend to reveal the grain boundaries of the polycrystalline material, which results in the high roughness observed. This effect is attributed to the fact that, at these grain sizes, the grinding wheel used is not necessarily sufficiently hard, and thus that, during the rotation of the grinding wheel, the blunted grains break more easily and new grains with brand new sharp edges, which tend to “scrape” the grain boundaries, are placed more easily at the surface.

In the process according to the present disclosure, use is thus preferably made of a grinding wheel with a smaller mesh (thus coarser abrasive grains) than the grinding wheels having very small grains conventionally used to obtain a very low surface roughness but which exhibits a hardness, which is not achievable for these grinding wheels having very small grains. Thus, use is preferably made of a grinding wheel, the size of the grains of which is between 2 μm and 3 μm (mesh of between 8,000 and 12,000). In addition, the hardness of the grinding wheel is preferably greater than the hardness achievable by a grinding wheel, the size of the grains of which is less than or equal to 1.5 μm (mesh is greater than or equal to 15,000).

This type of grinding wheel advantageously promotes the blunting of the abrasive grains during the removal of the at least partially work-damaged surface region without causing them to break and to be replaced by new grains.

Preferably, the relative movement of the grinding wheel and the silicon carbide slab is carried out so that the total thickness of the removal of matter does not exceed by more than 2.5 μm the thickness of the at least partially work-damaged surface region. Thus, if the at least partially work-damaged surface region exhibits a thickness of 500 nm, the total thickness of the removal of matter is preferably less than or equal to 3 μm. Not removing a total thickness of matter that exceeds by more than 2.5 μm the thickness of the work-damaged surface region advantageously makes it possible not to bring about the exposure, at the surface, of a new row of new grains with sharp edges.

During the relative axial movement of the grinding wheel and the polycrystalline silicon carbide slab, the relative axial speed of the grinding wheel and of the front face of the polycrystalline silicon carbide slab is between 0.05 μm/s and 0.5 μm/s, preferably between 0.1 μm/s and 0.45 μm/s, more preferably between 0.15 μm/s and 0.45 μm/s, up to the removal of the thickness of less than or equal to 3 μm from the polycrystalline silicon carbide slab.

A speed greater than 0.5 μm/s risks causing the splitting of the line of previously blunted abrasive grains, and thus the updating of a new line of abrasive grains, which it is desired to avoid, or the breakage of the grinding wheel. A speed less than 0.005 μm/s is too slow to be economically profitable.

The rotational speed of the grinding wheel during the polishing is, for example, between 10 m/s and 45 m/s, preferably between 10 m/s and 25 m/s. Thus, for a grinding wheel with a diameter of 300 mm, the rotational speed of the grinding wheel is between 500 rev/min and 1500 rev/min. A rotational speed of the grinding wheel less than 10 m/s unnecessarily increases the duration of the stage and is not economically advantageous. A speed greater than 45 m/s would risk bringing about the splitting of the previously blunted abrasive grains of the grinding wheel and/or the breakage of the grinding wheel and/or of the polycrystalline silicon carbide slab.

FIG. 3 gives a comparison of the results obtained by the implementation of such a process for the preparation of the front face of a polycrystalline silicon carbide slab (histograms (c) and (d)) with the results obtained by the implementation of a preparation process according to the state of the art (histograms (a) and (b)).

The histograms (a) and (b) correspond to fine grinding to remove a thickness on the order of 10 μm using a grinding wheel that is less hard than that preferably used in accordance with embodiments of the present disclosure. The histograms (c) and (d) correspond to polishing carried out according to the present disclosure by removing a thickness of 10 μm using a hard grinding wheel and by subsequently holding the rotating grinding wheel in contact with the front face of the polycrystalline silicon carbide slab for a period of time of less than 5 seconds in this embodiment.

The histograms (a) and (c) correspond to the percentage of polycrystalline silicon carbide slabs, the surface condition of the front face of which makes possible high-quality bonding of the front face to a single-crystal substrate. In other words, the histograms (a) and (c) correspond to the percentage of single-crystal substrates flawlessly bonded to a polycrystalline silicon carbide slab. The term “flaw” is understood to mean, for example, partial bonding of the single-crystal substrate, the single-crystal substrate layer not being transferred onto certain parts of the polycrystalline silicon carbide slab. The histograms (b) and (d) correspond for their part to the haze value measured on a polycrystalline silicon carbide slab by light scattering, for example, using the SURFSCAN® SP1 inspection system from KLA-Tencor or by the SICA88 inspection system from Lasertec. More precisely, it is a mean value measured at several points on a polycrystalline silicon carbide slab. The haze value is an indirect tool for measuring the roughness of the front face of the polycrystalline silicon carbide slab. This haze value results from a method using the optical reflectivity properties of the surface to be characterized and corresponds to an optical signal scattered by the surface, due to its microroughness: the greater the roughness of the surface, the greater the scattering on the surface and the greater the haze value measured.

Thus, it can be observed that the implementation of the process according to the present disclosure makes it possible to obtain a bonding efficiency on the order of 30%, which is greater than the efficiency of the process according to which a thickness on the order of 10 μm is removed, which is itself on the order of 10%. Furthermore, the haze value of a front face of a silicon carbide slab prepared by the process according to the present disclosure is less than the haze value of a front face prepared by the process according to the state of the art.

The holding of the rotating grinding wheel in contact with the front face of the polycrystalline silicon carbide slab can advantageously be carried out for a period of time greater than 30 seconds, and more preferably still, greater than 40 seconds, to maintain the frictional contact between the grinding wheel and the slab for as long as possible (while keeping the same row of previously blunted abrasive grains).

The holding of the rotating grinding wheel in contact with the front face of the polycrystalline silicon carbide slab for a period of time greater than 30 seconds, preferably a period of time greater than 40 seconds, is preferably divided up into several sequences, so that the contact between the grinding wheel and the front face of the polycrystalline silicon carbide slab is broken between each sequence by relative movement of the grinding wheel and the polycrystalline silicon carbide slab. In this case, the sum of the durations of each sequence during which the rotating grinding wheel is held in contact with the front face of the polycrystalline silicon carbide slab remains equal to the chosen period of time greater than 40 seconds. By way of example, the holding of the grinding wheel can comprise two sequences: a first sequence, the duration of which is between 5 seconds and 10 seconds, and then a second sequence, so that the sum of the durations of the first sequence and the second sequence is greater than or equal to 30 seconds, preferably greater than 40 seconds. Dividing up the period of rubbing between the rotating grinding wheel and the front face of the polycrystalline silicon carbide slab makes it possible to avoid overheating episodes and thus the splitting of the line of previously blunted abrasive grains.

In one possible embodiment, the polishing additionally comprises, subsequent to the halting of the relative movement and to the holding of the rotating grinding wheel in contact with the front face of the polycrystalline silicon carbide slab, an additional stage of relative movement of the grinding wheel and the front face of the polycrystalline silicon carbide slab. The additional stage of relative movement of the grinding wheel and of the front face can comprise, in a first step, the breaking of the contact between the grinding wheel and the front face and then, in a second step, the re-establishing of the contact. The additional stage of relative movement of the grinding wheel and the front face of the polycrystalline silicon carbide slab is in this case halted, for example, by the operator, as soon as contact of the grinding wheel and the front face of the polycrystalline silicon carbide slab is re-established, so as not to cause the previously blunted abrasive grains of the grinding wheel to split.

The additional stage of relative movement is carried out so as to result in the removal of a very small additional thickness from the polycrystalline silicon carbide slab, preferably an additional thickness from the polycrystalline silicon carbide slab of less than or equal to 1 μm, more preferably a thickness of less than 200 nm.

This additional stage of relative movement of the grinding wheel and the front face of the polycrystalline silicon carbide slab makes it possible to further reduce the roughness of the front face of the polycrystalline silicon carbide slab and thus to improve the surface quality thereof.

In FIG. 3, the histograms (e) and (f) respectively represent the efficiency and the haze value obtained following the implementation of the protocol followed for the histograms (c) and (d), supplemented by this additional stage removing a thickness of 1 μm. Thus, FIG. 3 shows the effectiveness of the stage, since the efficiency increases further to reach a value on the order of 80% and the haze value decreases further compared with the histogram (d).

In a particular embodiment of the present disclosure, the polycrystalline silicon carbide slab is rotated about an axis X perpendicular to the front face of the polycrystalline silicon carbide slab. The grinding wheel is itself in rotation about an axis Y perpendicular to the abrasive surface of the grinding wheel, the axis Y being parallel to the axis X.

The polycrystalline silicon carbide slab is, for example, a slab with a diameter of 150 mm and the grinding wheel is, for example, a grinding wheel with a diameter of 300 mm.

By way of example, the front face of the polycrystalline silicon carbide slab can be driven in rotation at a speed between 200 rev/min and 600 rev/min.

In this embodiment, the relative movement of the grinding wheel and the polycrystalline silicon carbide slab comprises, for example, the axial movement of the rotating grinding wheel along the Y axis, so as to bring the abrasive surface of the grinding wheel into contact with the front face of the polycrystalline silicon carbide slab, and then to remove the thickness of less than or equal to 3 μm from the slab under the effect of the pressure exerted by the grinding wheel in axial movement.

The movement of the grinding wheel along the Y axis is then blocked, the grinding wheel and the slab remaining in rotation about the X and Y axes, respectively, so as to maintain the contact between the grinding wheel and the front face of the polycrystalline silicon carbide slab for a period greater than 15 seconds, preferably a period greater than 30 seconds and more preferably a period greater than 40 seconds.

According to this embodiment, if the holding of the rotating grinding wheel in contact with the front face of the polycrystalline silicon carbide slab for a period with a duration of greater than 30 seconds, preferably for a period of time greater than 40 seconds, is divided up into several sequences as described above, the breaking of the contact between the grinding wheel and the front face can be carried out by translation along the Y axis of the grinding wheel held in rotation, so as to move the grinding wheel away from the front face of the slab. By way of example, the holding of the grinding wheel can comprise a first sequence with a duration of 10 seconds, a separation period of one minute, during which contact between the grinding wheel and the front face of the slab is broken, and a second sequence of 30 seconds.

The present disclosure applies to a process for the preparation of a polycrystalline silicon carbide slab. The process for the preparation of a polycrystalline silicon carbide slab comprises the thinning, by way of a grinding wheel of a first type, of a thick polycrystalline silicon carbide slab on its front face and optionally on its rear face, so as to obtain a thinned polycrystalline silicon carbide slab. Preferably, the polycrystalline silicon carbide slab thinned by way of the grinding wheel of the first type exhibits a thickness greater than or equal to 325 μm, more preferably a thickness of 350 μm.

The thick polycrystalline silicon carbide slab (for example, from 0.4 mm to 3 mm in thickness) can, for example, be produced by a deposition of p-SiC on a growth substrate (for example, a graphite substrate), typically a chemical vapor deposition at a temperature between 1200° C. and 1400° C.

Prior to the thinning by way of the grinding wheel of the first type, one or more very coarse grinding operations can optionally be carried out on the front face, preferably on the front face and on the rear face, of the thick silicon carbide slab.

The grinding wheel of the first type is a grinding wheel comprising abrasive grains coated in a binder, the size of the grains of the grinding wheel of the first type being between 10 μm and 30 μm (mesh of between 600 and 2,000). Given the size of the relatively large abrasive grains of the grinding wheel of the first type, the thinning of the polycrystalline silicon carbide slab thus corresponds to a grinding operation described as coarse by a person skilled in the art.

The thinning of the thick polycrystalline silicon carbide slab on its front face by way of the grinding wheel of the first type generates an at least partially work-damaged surface region on the front face, that is to say a region in which the crystal is disorganized exhibiting scratches and/or fractured zones. The smaller the mesh of the grinding wheel of the first type (thus the greater the size of the abrasive grains of the grinding wheel), the thicker the at least partially work-damaged surface region. Given the mesh range of the grinding wheel of the first type, the thickness of the work-damaged surface region is between 500 nm and 1 μm.

The process for the preparation of a polycrystalline silicon carbide slab according to the present disclosure additionally comprises the polishing of the front face of the polycrystalline silicon carbide slab thinned by way of the grinding wheel of the first type, the polishing being carried out according to any one embodiment of the polishing process described above by way of a grinding wheel of a second type.

The grinding wheel of the second type preferably exhibits the characteristics of sizes of grains and of hardness as stated above.

Thus, the grinding wheel of the second type preferably exhibits a hardness greater than the maximum hardness making possible the removal of a non-work-damaged layer of the same thickness as the at least partially work-damaged surface region generated by the grinding wheel of the first type and made of the same material as the surface region.

The grinding wheel of the second type preferably exhibits a size of grains of between 2 μm and 3 μm (mesh of between 8,000 and 12,000). In addition, the hardness of the grinding wheel of the second type is preferably greater than the hardness achievable by a grinding wheel, the size of the grains of which is less than or equal to 1.5 μm (mesh greater than or equal to 15,000).

In this process for the manufacture of a polycrystalline silicon carbide slab, the polishing of the front face of the slab, thinned beforehand by grinding by way of the grinding wheel of the first type, comprises the relative movement of the grinding wheel of the second type and the polycrystalline silicon carbide slab up to the removal of a thickness of less than or equal to 3 μm prior to the holding of the rotating grinding wheel in contact with the front face of the polycrystalline silicon carbide slab for a period of time greater than 15 seconds, preferably a period of time greater than 30 seconds, more preferably a period of time greater than 40 seconds. The removal of the thickness of less than or equal to 3 μm comprises the removal of the at least partially work-damaged surface region previously generated by the thinning carried out by way of the grinding wheel of the first type.

Thus, the process according to the present disclosure makes it possible to polish the front face of the polycrystalline silicon carbide slab directly after the thinning by coarse grinding on at least the front face of the slab, being freed from additional stages of finer grinding.

The present disclosure furthermore applies to a process for the manufacture of a multilayer structure, comprising the polishing of a p-SiC slab as set out above and the transfer of a thin layer of a single-crystal material from a substrate of the single-crystal material to the polycrystalline silicon carbide slab.

The single-crystal substrate is, for example, a single-crystal silicon carbide (m-SiC) substrate. Alternatively, the single-crystal substrate is a gallium nitride (GaN), indium phosphide (InP), diamond or silicon substrate. Optionally, an intermediate silicon dioxide (SiO₂) layer is disposed between the polycrystalline silicon carbide slab and the single-crystal substrate.

The transfer of the thin layer of the single-crystal material can be carried out according to the SMART CUT™ technology and can thus comprise an implantation of ionic entities in the single-crystal material substrate so as to form therein a weakened plane delimiting the thin layer to be transferred, the bonding of the single-crystal material substrate to the polycrystalline silicon carbide slab (if appropriate via one or more bonding layers), then the detachment (brought about by a heat treatment, a mechanical action or a combination of these means) of the single-crystal material substrate along the weakened plane, so as to transfer the thin active layer to the polycrystalline silicon carbide slab. The single-crystal material substrate can be subjected to mechanical or chemical mechanical polishing before bonding. The process for the manufacture of the composite structure can additionally comprise the formation of electronic components, in particular, of power or radiofrequency components, in the transferred thin layer.

The single-crystal material substrate on the polycrystalline silicon carbide slab is bonded, for example, by bonding, such as ADB bonding. ADB bonding comprises, for example, the deposition of a silicon layer with a thickness preferably between 4 nm and 20 nm, more preferably a thickness of 10 nm, on each of the surfaces to be bonded. This is because a silicon layer with a thickness of less than 4 nm brings about risks of bubbling. Alternatively, the single-crystal material substrate on the polycrystalline silicon carbide slab is bonded by way of surface activation bonding (SAB). The polishing process according to the present disclosure advantageously makes it possible to achieve the very low roughness demanded by these bonding methods.

1. A method of polishing a front face of a polycrystalline silicon carbide slab having a surface region at least partially work-damaged from grinding, the method comprising:
relative movement of a rotationally driven grinding wheel and the polycrystalline silicon carbide slab until a layer comprising the at least partially work-damaged surface region and exhibiting a thickness of less than or equal to 3 μm is removed from the polycrystalline silicon carbide slab, with the rotating grinding wheel in contact with the front face of the slab; and
halting the relative movement and maintaining the rotating grinding wheel in contact with the front face of the polycrystalline silicon carbide slab for a period of time greater than 15 seconds.

2. The method of claim 1, wherein the grinding wheel exhibits a greater hardness than a maximum hardness enabling removal of a non-work-damaged layer of a same thickness as the at least partially work-damaged surface region made of polycrystalline silicon carbide.

3. The method of claim 1, wherein the grinding wheel comprises diamond grains coated in a binder, the size of the diamond grains being greater than 2 μm (mesh 12,000).

4. The method of claim 1, wherein, during the relative movement of the grinding wheel and the polycrystalline silicon carbide slab, a relative speed of the grinding wheel and the front face of the polycrystalline silicon carbide slab is between 0.05 μm/s and 0.5 μm/s, until the layer having the thickness of less than or equal to 3 μm has been removed from the polycrystalline silicon carbide slab.

5. The method of claim 1, wherein the maintaining of the rotating grinding wheel in contact with the front face of the polycrystalline silicon carbide slab is carried out for a period of time greater than or equal to 30 seconds.

6. The method of claim 5, wherein the maintaining of the rotating grinding wheel in contact with the front face of the polycrystalline silicon carbide slab for a period of time of greater than or equal to 30 seconds is divided up into several sequences.

7. The method of claim 1, further comprising, subsequent to the halting of the relative movement and to the maintaining of the rotating grinding wheel in contact with the front face of the polycrystalline silicon carbide slab, an additional stage of relative movement of the grinding wheel and the front face of the polycrystalline silicon carbide slab until an additional thickness of less than or equal to 1 μm has been removed from the polycrystalline silicon carbide slab, with the rotating grinding wheel in contact with the front face of the slab, of.

8. The method of claim 1, wherein the rotational speed of the grinding wheel during the polishing is between 10 m/s and 45 m/s.

9. The method of claim 1, wherein, during the polishing, the front face of the polycrystalline silicon carbide slab is driven in rotation at a speed of between 200 rev/min and 600 rev/min.

10. A method of manufacturing a polycrystalline silicon carbide slab, comprising:
thinning by grinding of a thick polycrystalline silicon carbide slab on at least a front face of the slab, so as to obtain a thinned polycrystalline silicon carbide slab; and
polishing the front face of the thinned polycrystalline silicon carbide slab, the polishing being carried out by a method according to claim 1.

11. The method of claim 10, wherein the thinning of the thick polycrystalline silicon carbide slab on at least a front face of the slab is carried out by way of a grinding wheel, a size of grains of the grinding wheel between 10 μm (mesh 2000) and 30 μm (mesh 600).

12. A method of preparing a multilayer structure, comprising:
manufacturing a polycrystalline silicon carbide slab by a method according to claim 10;
providing a substrate comprising a donor of a layer to be transferred; and
transferring the layer to be transferred from the donor substrate onto a front face of the polycrystalline silicon carbide slab.

13. The method of claim 12, wherein the donor substrate is a single-crystal silicon carbide substrate.

14. The method of claim 12, wherein the transferring comprises:
forming a weakened zone by implantation of atomic entities in the donor substrate so as to delimit the layer to be transferred;
bonding the implanted face of the donor substrate to the front face of the polycrystalline silicon carbide slab; and
detaching the donor substrate along the weakened zone.

15. The method of claim 14, wherein the bonding is direct bonding.

16. The method of claim 4, wherein the relative speed of the grinding wheel and the front face of the polycrystalline silicon carbide slab is between 0.1 μm/s and 0.45 μm/s until the layer having the thickness of less than or equal to 3 μm has been removed from the polycrystalline silicon carbide slab.

17. The method of claim 16, wherein the relative speed of the grinding wheel and the front face of the polycrystalline silicon carbide slab is between 0.15 μm/s and 0.45 μm/s until the layer having the thickness of less than or equal to 3 μm has been removed from the polycrystalline silicon carbide slab.

18. The method of claim 5, wherein the maintaining of the rotating grinding wheel in contact with the front face of the polycrystalline silicon carbide slab is carried out for a period of time greater than or equal to 40 seconds.

19. The method of claim 18, wherein the maintaining of the rotating grinding wheel in contact with the front face of the polycrystalline silicon carbide slab for a period of time of greater than or equal to 40 seconds is divided up into several sequences.

20. The method of claim 8, wherein the rotational speed of the grinding wheel during the polishing is between 10 m/s and 25 m/s.
